(19) United States
(12) Patent Application Publication
(10) Pub. No.: US 2011/0309424 A1
(43) Pub. Date: Dec. 22, 2011

(54) STRUCTURE OF MEMORY DEVICE AND PROCESS FOR FABRICTING THE SAME

(75) Inventors: Ming-Te WEI, Xihu Township (TW); Po-Chao Tsao, Xinzhuang City (TW); Jun-Chi Huang, Dali City (TW); Chia-Wei Huang, Tainan City (TW); Chuan-Hsien Fu, Zhonghe City (TW); Chih-Fang Tsai, Kaohsiung City (TW); Te-Hung Wu, Xinshi Township (TW)

(73) Assignee: UNITED MICROELECTRONICS COR

(21) Appl. No.: 12/819,246

(22) Filed: Jun. 21, 2010

(51) Int. Cl. H01L 29/788; H01L 21/336

(52) U.S. Cl. 257/316; 438/266; 257/E29.3; 257/E21.422

(57) ABSTRACT

A structure of a memory cell of a static random memory device and a process for fabricating the same are disclosed. The memory cell includes a substrate having an active region including an N-well and a shallow trench isolation structure; a first gate and a second gate formed over the substrate; a halo region, a LLD, and a source and drain region formed on two sides of the first gate; an interlevel dielectric layer covering the substrate, the first and second gates; and a contact penetrating the interlevel dielectric layer and extending to the source and drain region, no halo region is formed under the contact.

### BACKGROUND

1. Field of the Invention

This invention relates generally to a semiconductor device and a process for fabricating the same; and more particularly to a structure of a memory device, and a process for fabricating the same.

2. Description of the Related Art

A memory cell of static random access memory (SRAM) usually comprises of a pair of MOS transistors that form a flip-flop, two MOS transistors (transfer gates) that control the connection/disconnection of the output terminal and the data line, and two resistors that act as the load for the flip-flop. However, as the integration level of SRAM has increased in recent years, SRAM is beginning to use memory cells in which the two resistors that act as the load for the flip-flop are replaced by two MOS transistors configured using thin polycrystalline silicon films. A single memory cell is thereby configured using six MOS transistors. As the technology continues to shrink, leakage current of devices is becoming a prime concern as it is indicative of faults in the devices. Such faults may not affect logical behavior and may pass the functional and logical testing, but may malfunction over time, causing reliability hazards. Many of such faults cause elevated quiescent power supply current (I_{DDQ}), which is typically greater than the I_{DDQ} of a fault-free device.

One of the common faults is due to diode leakage. During the fabrication of the share-contact, over etching of the contact opening may occur which may damage the spacer and the STI and also partially remove the LDD and Halo regions so that the metal filled into the contact opening creates the share contact to have contact with Halo region (N-mixing). Consequently, upon application of voltage onto the share contact, instead of enabling S/D(p+) and N-well to generate a p-n junction, leakage occurs via the Halo region (N-mixing) and N-well.

Therefore, one of the objects of the present invention is to develop a structure and a process for fabricating a memory cell for reducing the diode leakage and increasing the reliability of the memory device.

### BRIEF SUMMARY

One embodiment realizes a memory cell in which the aforementioned diode leakage may be reduced to improve the reliability of the memory device.

One embodiment provides a process of fabricating a memory cell for reducing the diode leakage for improving the reliability of the memory device.

One embodiment is a structure of the memory cell of a memory device comprising a substrate of first conductive type and a shallow trench isolation (STI) structure; a PMOS and a gate formed over the substrate, wherein the gate is formed over the STI structure; a dielectric layer covering the substrate, the PMOS and the gate; and a contact penetrating the dielectric layer and extending both to the second gate and to the source/drain region of the first gate. The PMOS comprises a gate, Halo regions of first conductive type, LDD of second conductive type and S/D regions of second conductive type formed on both sides of the gate.

One embodiment is a fabrication process comprising at least providing a substrate of first conductive type comprising an active region including and a shallow trench isolation (STI) structure formed therein; forming a first gate and a second gate on the active region and the STI respectively; covering the second gate; forming halo regions of first conductive type, LLD regions of second conductive type, and source/ drain region of second conductive type in the substrate; sequentially forming an etching stop layer and a dielectric layer over the substrate; and forming a contact penetrating the dielectric layer and extending both to the second gate and to the source/drain region of the first gate.

In an embodiment, the step of forming the Halo regions includes disposing a photoresist layer to cover the substrate, the first and second gates, patterning the photoresist layer to expose the first gate, and performing an ion implantation to form the halo regions on both sides of the first gate.

In an embodiment, the halo regions are selectively formed on the sides of the first gate and no halo region is formed in the active region and under the contact. Consequently, a larger source/drain region compared to the conventional source/drain region may be formed. Because no halo regions are formed under the contact area, the p-n junction may be effectively generated upon application of voltage to the contact.

The characteristics and the advantages of the present invention will be apparent from the following description of an embodiment thereof given by way of indicative and non-limiting example with reference to the annexed drawings.

### BRIEF DESCRIPTION OF THE DRAWINGS

These and other features and advantages of the various embodiments disclosed herein will be better understood with respect to the following description and drawings, in which like numbers refer to like parts throughout.

FIGS. 1A-1E are cross sectional views illustrating process steps for fabricating a conventional memory cell of a memory cell of a memory device.

FIGS. 2A and 2B respectively illustrate a top view and a cross sectional view of an example structure of a memory cell of a memory device according to an embodiment of the present invention.

FIGS. 3A-3I are cross sectional views illustrating process steps for fabricating a memory cell of a memory device according to an embodiment of the present invention.

### DETAILED DESCRIPTION

In the following description, numerous specific details are set forth such as specific steps and configurations to provide a thorough understanding of the present invention. However, it will be obvious to those skilled in the art that the present invention may be practiced without such specific details.

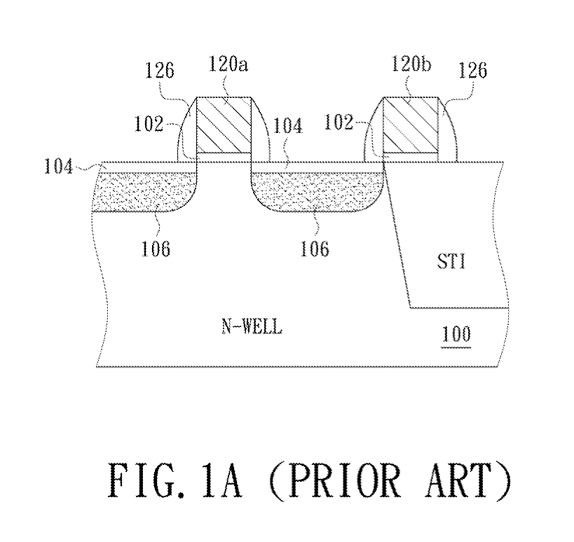

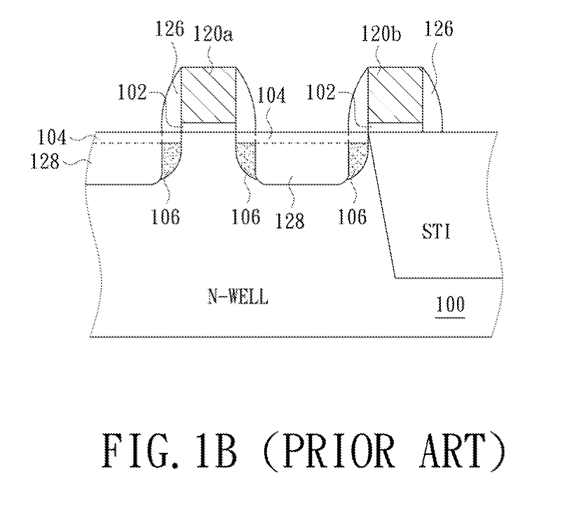

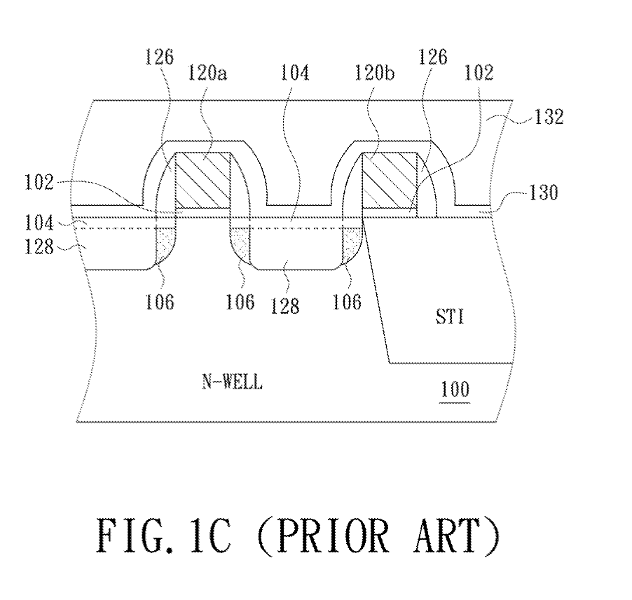

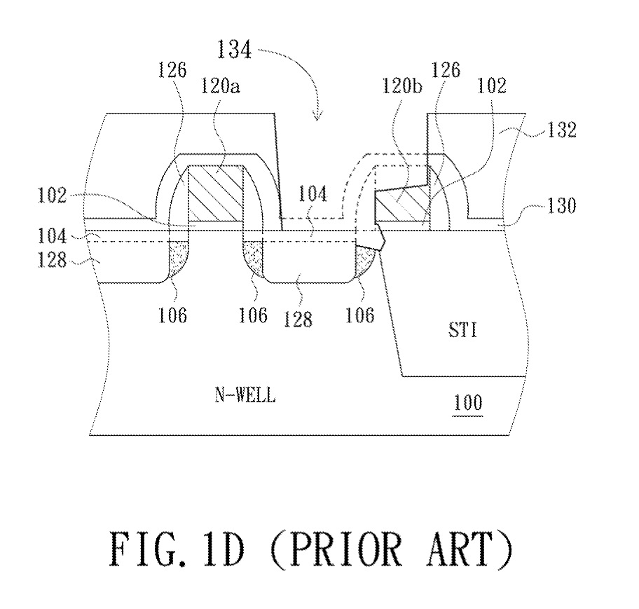

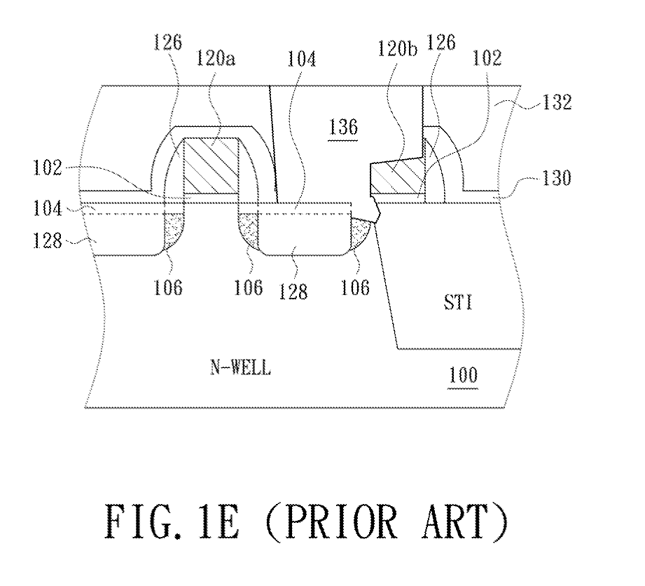

Hereinafter a process for fabricating a conventional memory cell may be briefly described. FIGS. 1A-1E illustrate a process for fabricating a conventional memory cell. As illustrated in FIGS. 1A-1E, first, a substrate 100 including an N-well and a shallow trench Isolation (STI), a first gate 120a and a second gate 120b formed over the N-well and the STI respectively is provided. A dielectric layer 102 may be formed between the substrate 100 and the first and second gates 120a and 120b. Next, ion implantation processes are carried out to form LDD regions 104 and halo regions 106 on both sides of the first and second gates 120a and 120b. Thereafter spacers 126 are formed on the sidewalls of the first and second gates 120a and 120b. Next, the source and drain regions 128 are formed on both sides of the first and second gates 120a and 120b. Next, an etching stop layer 130 and a dielectric layer 132 are sequentially formed over the substrate 100 and covering the first and second gates 120a and 120b. Next, an etching process may be carried out to etch the dielectric layer 132 until the etching stop layer 130 is exposed to form a contact opening 134. Next, a metal layer may be formed to fill the contact opening 134 to form a contact 136.

During the fabrication of the contact opening 134, over etching may occur which may damage the spacers 126 and the STI, and may also partially remove the LDD 104 and halo regions 106 so that the metal layer filled into the contact opening 134 creates the contact 136 to have contact with halo regions 106 (N-mixing). Consequently, upon application of voltage onto the contact, instead of enabling S/D(p+) and N-well to generate a p-n junction, leakage occurs via the halo region (N-mixing) and N-well.

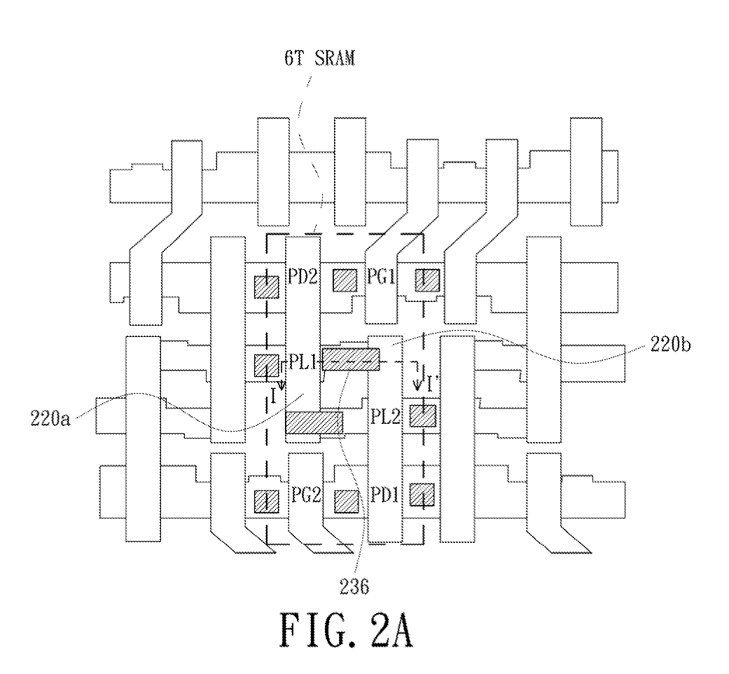

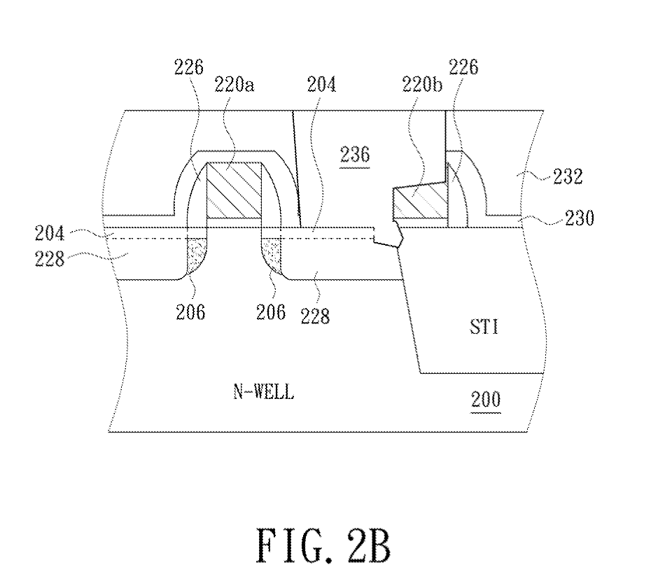

Hereinafter an example structure of a memory cell according to an embodiment is described as follows. This embodiment is exemplified with a static random memory (SRAM) cell device, which may be able to resolve the aforementioned problems of the prior art. FIG. 2A illustrates a top view of a 6T SRAM cell device and FIG. 2B illustrates a cross section view of a 6T SRAM cell device taken along line I-I′. Referring to FIGS. 2A and 2B, the SRAM cell device comprises a substrate 200 of first conductive type, for example p type, having an active region and a STI; a first gate 220a and a second gate 220b, wherein the first gate 220a is formed on the active region and the second gate 220b is formed on the STI, and spacers 226 formed on the sidewalls of the gates 220a and 220b; a gate dielectric layer 202 formed between the first and second gates 220a and 220b; a dielectric layer 232 covering the substrate 200, the first and second gates 220a and 220b; and a contact 236 penetrating the dielectric layer 232. LLD regions 204 of second conductive type, for example n type, halo regions 206 of first conductive type, and source/drain regions 228 of second conductive type are formed on two sides of the first gate. According to the present embodiment, the halo regions 104 of first conductive type are selectively formed on the sides of the first gate 220a, and halo regions 206 are not formed in the active region adjacent to the second gate 220b and under the contact 236.

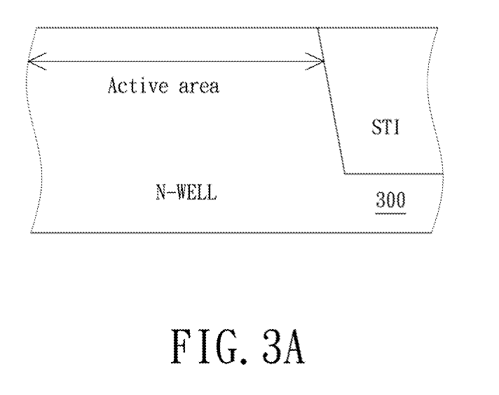

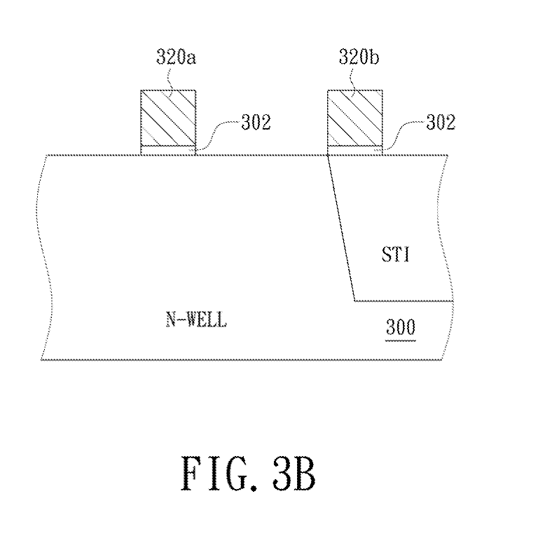

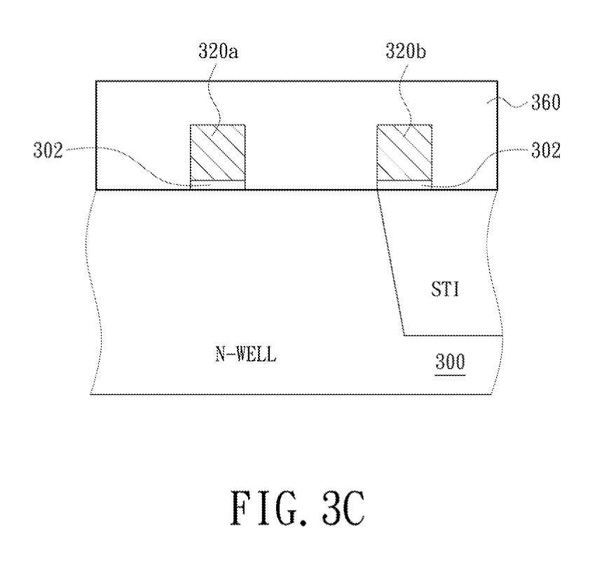

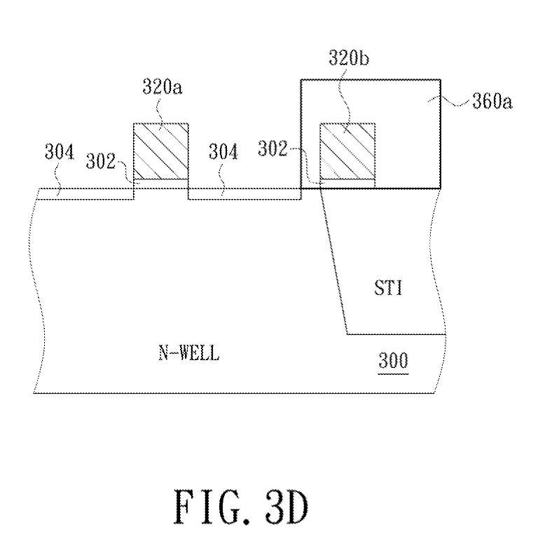

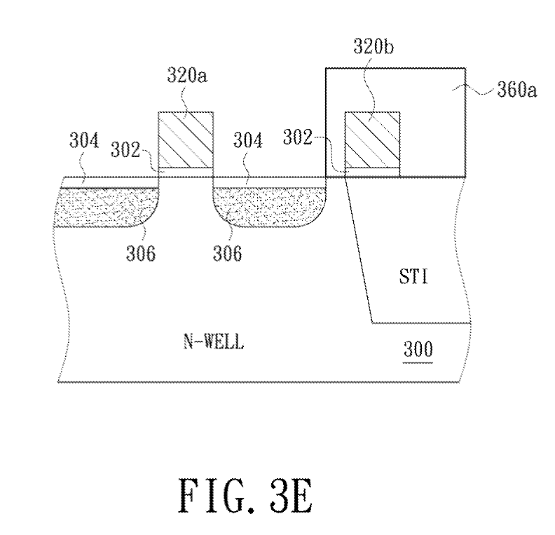

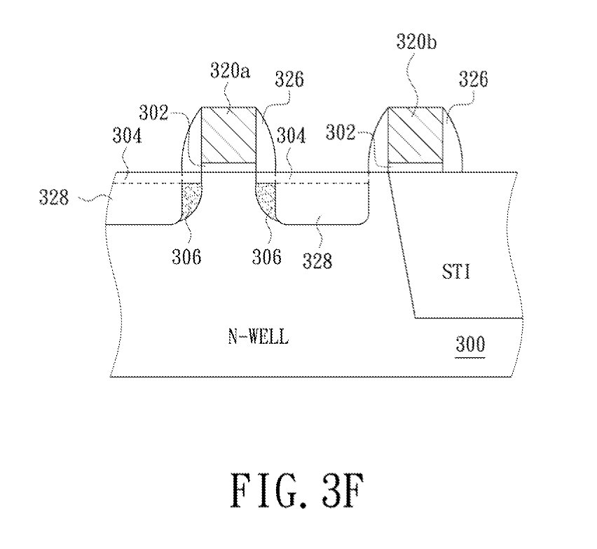

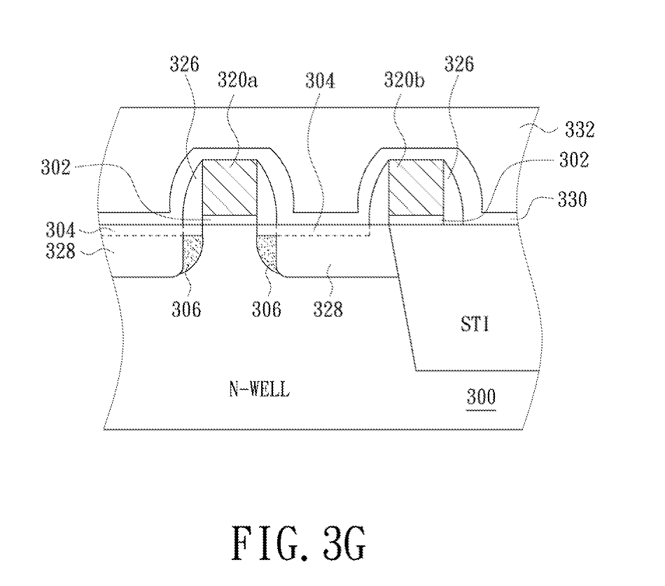

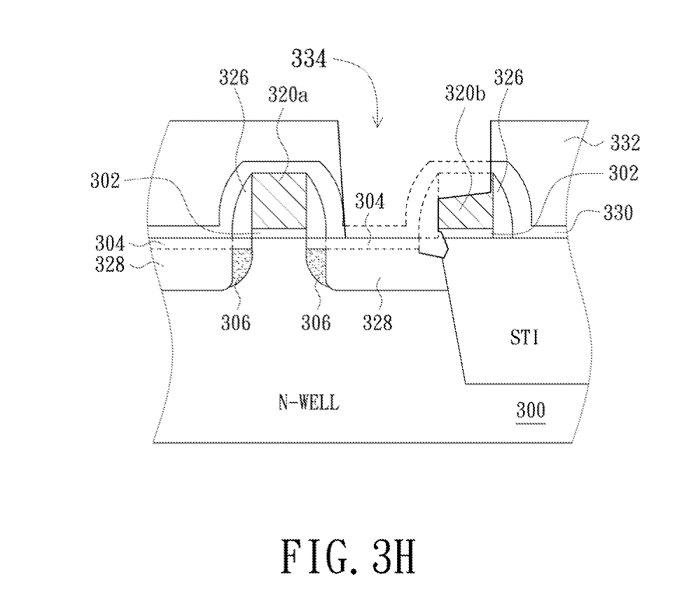

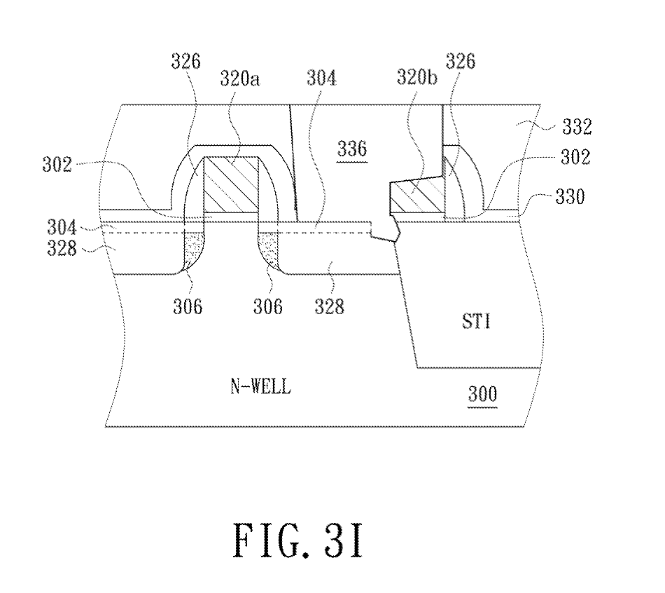

Hereinafter a process for fabricating a memory cell of a memory device is described as follows. FIGS. 3A to 3E are cross-sectional views illustrating a process for fabricating a memory cell of a memory device according to an embodiment of the present invention. This embodiment is exemplified with a static random memory cell device.

Referring to FIG. 3A, a substrate 300 of first conductive type, for example p type, having an active region and a shallow trench isolation (STI) structure is provided.

Referring to FIG. 3B, a thin oxide layer is formed on the substrate 300. The oxide layer serves as a gate dielectric layer 302. The gate dielectric layer 302 is, for example, comprised of silicon oxide, and may be formed by, for example, a thermal oxidization process or a chemical vapor deposition (CVD) process. Gates 320a and 320b are formed over N-well and the STI structure respectively. Each of the gates 320a and 320b may be comprised of a conductive layer composed of, for example, an amorphous silicon layer and a metallic silicide layer.

Referring to FIG. 3C, a photoresist layer 360 is formed over the substrate 300 to cover the gates 320a and 320b.

Referring to FIG. 3D, the photoresist 360 is patterned to expose the entire gate 120a and cover the entire gate 120b. Next, an ion implantation is carried out to form LLD regions 304 of second conductive type, for example n type, in the substrate 300 on two sides of the gate 320a.

Referring to FIG. 3E, with the patterned photoresist 360a still covering the entire gate 120b, another ion implantation is carried out to form halo regions 306 of first conductive type in the substrate 300 on two sides of the gate 320a. Because the gate 120b is covered, no halo regions are formed in the substrate 300 on the sides of the gate 320b or at the area in the substrate where a contact (336) may subsequently extend to.

Referring to FIG. 3F, the patterned photoresist layer 360a is removed. Spacers 326 are formed on sidewalls of the gates 320a and 320b. The spacers 326 may be formed, for example, by forming a material layer, for example comprised of silicon nitride, over the substrate 300 to cover the gates 320a and 320b, and removing a portion of the material layer, for example, by performing an etching process, to form the spacer 326 on the sidewalls of the gates 320a and 320b. Next, an ion implantation process is carried out to form source/drain region 328 on both sides of the gate 320a. Because no halo region is formed adjacent to the gate 320b, the impurities (ions) may diffuse during a thermal process and extend to the STI thereby form a comparatively a larger source/drain region.

Referring to FIG. 3G, an etching stop layer 330 and a dielectric layer 332 are sequentially formed over the substrate 300 to cover the gates 320a and 320b. Next, an etching process is conducted to remove a portion of the dielectric layer 332 until a portion of the etching stop layer 330 is exposed to form, for example, a contact opening 334. The etching process, for example, includes the steps of sequentially forming a hard mask layer on the dielectric layer 332 (not shown) and a patterned photoresist layer (not shown) on the over the hard mask layer, removing a portion of the hard mask layer using the patterned photoresist layer as a mask to expose a portion of the dielectric layer 332; removing the patterned photoresist layer; and removing a portion of the dielectric layer 332 until a portion of the etching stop layer 330 is exposed to form the contact opening 334 in the dielectric layer 332 using the hard mask layer as an etching mask.

Referring to FIG. 3H, a metal layer is formed over the substrate 300 to fill the metal layer into the contact opening 334 to form a contact 136.

When over-etching occurs, the contact opening 334 may etch off the etching stop layer 330 and portions of the spacer 326 and gate 320b, and extend to the source/drain region 328. It is to be noted that since no halo region 304 is formed in the substrate 300 under the contact 336 (shown as FIG. 31, upon application of voltage to the contact, p-n junction may be effectively generated and thereby reduce the possibility of diode leakage. Thus, the reliability of the memory device may be effectively increased.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A structure of a static random memory device, comprising:
a substrate, comprising an active region of a first conductive type and a shallow trench isolation structure;
a first gate formed on the active region and a second gate formed on the shallow trench isolation structure;
a halo region of the first conductive type, a LLD of a second conductive type, and a source/drain region of the second conductive type formed in the active region on two sides of the first gate;
a dielectric layer covering the substrate, the first and second gates; and
a contact penetrating the dielectric layer and extending both to the second gate and to the source/drain region of the first gate, wherein no halo region is formed in the active region adjacent to the second gate and under the contact.

2. A process for fabricating a static random access memory device, comprising:
providing a substrate of a first conductive type comprising an active region and a shallow trench isolation structure;
forming a first gate on the active region and second gate on the shallow trench isolation structure;
selectively forming LLD regions of second conductive type and halo regions of first conductive type in the substrate on both sides of the first gate such that halo regions of first conductive type is not formed in the active region;
forming spacers on the sidewalls of the first and second gates;
forming source/drain region in the substrate on both sides of the first and second gates;
forming a dielectric layer over the substrate covering the first and second gates; and
forming a contact penetrating the dielectric layer and extending both to the second gate and to the source/drain region of the first gate, wherein no halo region is formed in the active region and under the contact.

3. The process for fabricating a static random access memory device as claimed in claim 2, further comprising a step of covering the second gate prior to the step of forming the halo region of first conductive type and the LDD region of second conductive type.

4. The process for fabricating a static random access memory device as claimed in claim 3, wherein the first conductive type is a p type and the second conductive type is an n type.

5. The process for fabricating a static random access memory device as claimed in claim 3, wherein the step of covering the second gate comprising forming a photoresist layer over the substrate covering the first and second gates and patterning the photoresist layer to expose the first gate.

6. The process for fabricating a static random access memory device as claimed in claim 2, wherein the step of forming the spacers on the sidewalls of the first and second gates comprises disposing a material layer over the substrate covering the first and second gates and performing an etching process to remove a portion of the material layer to form the spacers.

7. The process for fabricating a static random access memory device as claimed in claim 2, further comprising a step of forming a gate oxide layer over between the substrate and the first and second gates.

8. The process for fabricating a static random access memory device as claimed in claim 7, wherein the gate oxide layer comprises silicon oxide.

9. The process for fabricating a static random access memory device as claimed in claim 7, wherein the gate oxide layer is formed by performing a thermal oxidization process or a chemical vapor deposition (CVD) process.

10. The process for fabricating a static random access memory device as claimed in claim 2, wherein the step of forming the contact comprises:
forming a hard mask layer over the dielectric layer;
a patterned photoresist layer on the hard mask layer;
removing a portion of the hard mask layer using the patterned photoresist layer as a mask to expose a portion of the dielectric layer;
removing the patterned photoresist layer; and
removing a portion of the dielectric layer, using the hard mask layer as an etching mask, until a portion of the etching stop layer is exposed to form the contact opening in the dielectric layer; and
filling a metal layer into the contact opening to form the contact.

11. A process for fabricating a static random access memory device, comprising:
providing a substrate of first conductive type comprising an active region and a shallow trench isolation structure;
forming a first gate on the active region and second gate on the shallow trench isolation structure;
forming a patterned photoresist layer over the substrate to cover the second gate;
selectively forming LLD region of second conductive type and halo region of first conductive type on both sides of the first gate after forming the patterned photoresist layer over the substrate covering the second gate such that halo region is not formed in the active region;
forming spacers on the sidewalls of the first and second gates;
forming source drain regions in the substrate on both sides of the first and second gates;
forming an interlevel dielectric layer over the substrate covering the first and second gates; and
forming a contact penetrating the interlevel dielectric layer and extending both to the second gate and to the source/drain region of the first gate, wherein no halo region is formed under the contact.

12. The process for fabricating a static random access memory device as claimed in claim 11, wherein the step of forming the patterned photoresist layer to cover the second gate comprises forming a photoresist layer over the substrate covering the first and second gates and patterning the photoresist layer to expose the first gate.

13. The process for fabricating a static random access memory device as claimed in claim 11, wherein the step of forming the spacers on the sidewalls of the first and second gates comprises disposing a material layer over the substrate covering the first and second gates and performing an etching process to remove a portion of the material layer to form the spacers.

14. The process for fabricating a static random access memory device as claimed in claim 11, further comprising a step of forming a gate oxide layer over between the substrate and the first and second gates.

15. The process for fabricating a static random access memory device as claimed in claim 14, wherein the gate oxide layer comprises silicon oxide.

16. The process for fabricating a static random access memory device as claimed in claim 15, wherein the gate oxide layer is formed by performing a thermal oxidization process or a chemical vapor deposition (CVD) process.

17. The process for fabricating a static random access memory device as claimed in claim 11, wherein the step of forming the contact comprises:
forming a hard mask layer over the dielectric layer;
a patterned photoresist layer on the hard mask layer;
removing a portion of the hard mask layer using the patterned photoresist layer as a mask to expose a portion of the dielectric layer;
removing the patterned photoresist layer;
removing a portion of the dielectric layer, using the hard mask layer as an etching mask, until a portion of the etching stop layer is exposed to form the contact opening in the dielectric layer; and
filling a metal layer into the contact opening to form the contact.
